(19) United States
(12) Patent Application Publication
(10) Pub. No.: US 2026/0314485 A1
(43) Pub. Date: Oct. 8, 2026

(54) SEMICONDUCTOR DEVICE WITH AN EMBEDDED PASSIVE COMPONENT AND METHOD OF MAKING THE SAME

(71) Applicant: TEXAS INSTRUMENTS INCORPORATED, DALLAS, TX (US)

(72) Inventors: Jovenic R. Esquejo, Baguio City (PH); Alliyah Veil Papio, CALASIAO (PH); Von Mark Mendoza, BAGUIO CITY (PH); Kenneth Tungol, BAGUIO CITY (PH)

(21) Appl. No.: 19/170,613

(22) Filed: Apr. 4, 2025

(51) Int. Cl. H10W 90/00; H10W 70/04; H10W 70/40; H10W 74/01; H10W 44/00; H10W 72/50

(52) U.S. Cl. CPC H10W 90/00; H10W 70/041; H10W 70/042; H10W 70/048; H10W 70/411; H10W 70/429; H10W 74/016; H10W 44/601; H10W 72/536; H10W 72/5363; H10W 90/756

(57) ABSTRACT

A semiconductor package is disclosed that includes a die and a leadframe. The leadframe can include a die pad to which the die can be coupled and a set of leads comprising surfaces. A passive component can be coupled to the surfaces of the set of leads, which can be at least in electrical connection with the die.

### TECHNICAL FIELD

This disclosure relates to semiconductor packaging. More particularly, this disclosure relates to a semiconductor device with an embedded passive component and a method of making the same.

### BACKGROUND

A semiconductor device is an electronic component made from semiconductor material with controlled electrical conductivity. The term "semiconductor device" can refer to various types of electronics, including individual components, such as diodes, transistors, photonic devices and power devices and integrated circuits (ICs). An IC can incorporate multiple electronic components and/or circuits into a single chip. A chip, also known as a microchip, silicon chip, or die, is a piece of semiconductor material, usually silicon, on which the IC is fabricated. ICs are built on a wafer and once complete, the wafer is cut to provide individual dies. The die can be mounted on a package substrate or a leadframe and encapsulated in a molding to form an IC package or semiconductor package (device). The IC package is designed to be mounted on a printed circuit board (PCB) and connected to other components in an electronic system.

A first example relates to a semiconductor package that includes a die and a leadframe. The leadframe can include a die pad to which the die can be coupled and a set of leads comprising surfaces. A passive component can be coupled to the surfaces of the set of leads, which can be at least in electrical connection with the die.

A second example relates to a method that can include providing one or more leadframe assemblies. Each leadframe assembly can include a die pad and a set of leads. Each lead of the set of leads can include an inner lead arm extending toward the die pad from a periphery portion of a respective leadframe assembly. The method can further include attaching a passive component to inner lead arms, attaching a die to the die pad of each leadframe assembly, forming electrical connections between the die and the respective leadframe assembly, applying a molding material to encapsulate at least a portion of each leadframe assembly to provide one or more molded leadframe assemblies and processing the one or more molded leadframe assemblies to form one or more semiconductor packages.

A third example relates to a method that can include providing a leadframe strip that can include multiple leadframe assemblies. Each leadframe assembly can include a die pad and a set of leads. Each lead of the set of leads can include an inner lead arm extending toward the die pad from a periphery portion of the leadframe assembly. The method can further include attaching a passive component to the inner lead arms of each leadframe assembly in the leadframe strip, attaching a die to the die pad of each leadframe assembly, forming electrical connections between each die and the corresponding leadframe assembly, applying a molding material to encapsulate at least a portion of each leadframe assembly, thereby providing a molded leadframe strip and processing the molded leadframe strip to form a plurality of semiconductor packages by separating individual leadframe assemblies from the molded leadframe strip.

### BRIEF DESCRIPTION OF THE DRAWINGS

FIG. 1A illustrates a diagram of an example of a semiconductor device.

FIG. 1B illustrates a diagram of an example of a passive component coupled to inner lead arms of a semiconductor device.

FIGS. 2A-2D illustrates examples of leadframe assemblies.

FIGS. 3-10 illustrates stages of a method for forming a semiconductor device.

FIG. 11 illustrates a flowchart of an example of a first method for making a leadframe strip.

FIG. 12 illustrates a flowchart of an example of a second method for making a leadframe strip.

FIG. 13 illustrates a flowchart of an example of a method for making a plurality of semiconductor packages.

### DETAILED DESCRIPTION

This description relates to a semiconductor device and a method of making the same, where the semiconductor device incorporates one or more passive components within a package itself. A Quad Flat Package (QFP) is a type of surface-mount integrated circuit package characterized by a flat, rectangular or square body with leads extending outward from sides of the QFP. The leads can be thin, gull-wing shaped and allow for soldering of the QFP to a printed circuit board (PCB). QFPs have a compact design and high lead count, making such semiconductor devices suitable for various application, such as microcontrollers, microprocessors and application specific integrated circuits (ASICs).

Existing QFPs do not allow for the integration of passive components (e.g., capacitors) within a package structure. This is because a QFP uses a leadframe-based design, where leads extend outward from a package body and are designed with specific widths for electrical isolation, mechanical stability and manufacturability. A width of these leads is set (or designed) to allow for proper signal transmission while minimizing crosstalk and interference. Due to spacing and manufacturing constraints, reducing the lead width in the QFP to accommodate additional passive elements within the package is not feasible. Narrower leads would introduce challenges in forming reliable interconnects, increasing the risk of electrical shorts, parasitic coupling and can reduce a mechanical integrity of the package. Existing QFP designs that rely on external passive components mounted on a PCB. This increases PCB complexity, as additional routing space is needed and can introduce signal integrity issues due to increased parasitic inductance and resistance. Moreover, externally mounted passive components are positioned away from a die within the QFP, resulting in less effective power stabilization and noise filtering in some applications of the QFP. For example, when high-frequency noise enters a package unit (the QFP), voltage fluctuations can occur, leading to instability in the electrical operation of the die.

Examples are disclosed relating to a semiconductor device (or package) and a method of making the same, where the semiconductor device includes one or more passive components integrated within the package. In certain examples, a semiconductor package can be fabricated according to examples herein, wherein the one or more passive components (e.g., capacitor(s)), are internally attached to a leadframe of the semiconductor package. Unlike existing leadframe-design, such as QFP designs, a semiconductor device can be fabricated according to examples herein with integrated passive component(s). In some examples, the semiconductor device can be fabricated (or produced) using a capacitor-integrated leadframe (ChiCap) Technique, as described herein. For example, the ChiCap Technique can be used during fabrication of the semiconductor device to couple each passive component to the leadframe. Existing QFP designs rely on externally mounted passive elements on a PCB. The ChiCap Technique uses a leadframe that is fabricated with inner lead arm pairs with dimensions that can accommodate the attachment of a passive component(s) during semiconductor package fabrication.

For example, a passive component (a capacitor as an example) can be electrically coupled to first and second terminal segments of one of the first and second inner lead arms. The passive component is coupled to the first and second terminal segments on bottom surfaces of the these terminal segments on a back side of the leadframe. Each pair of inner lead arms has a structural configuration (e.g., a width) that allows these inner lead portions of the leadframe to support the passive component. A passive component mounted to the first and second terminal segments of the leadframe can be referred to as an embedded passive element herein. By embedding the passive element with the semiconductor package eliminates the need for external passive components mounted on a PCB, thereby reducing PCB space consumption and allowing for higher-density semiconductor devices to be mounted on the PCB. Internally housing passive components within the package structure allows for a more compact and high-density package design, reducing reliance on externally mounted passive components. Additionally, integrating passive elements into the package structure optimizes PCB layout by decreasing the area needed for external passive component placement, allows for a greater number of semiconductor packages to be mounted the PCB. As such, the packaging technology described herein improves manufacturing efficiency by simplifying board-level assembly and eliminating the need for attaching external passive components.

In some examples, an embedded passive element can be electrically coupled in series with corresponding passive element support leads of the leadframe (e.g., the first and second inner leader arms), thereby enhancing power stability of the semiconductor device by reducing voltage fluctuations and improving noise filtering. This configuration provides more effective suppression of high-frequency noise compared to QFP designs that rely on externally mounted passive elements. In some examples, the embedded passive element is a capacitor and the capacitor can function as a decoupling capacitor and thus can be used to enhance the power integrity of the semiconductor device. By incorporating the decoupling capacitor into the package this reduces voltage fluctuations and suppresses high-frequency noise at power supply connections of the die. Additionally, by integrating capacitors within the package this can improve the transient response of the semiconductor device by stabilizing voltage levels during rapid changes in power demand and enhances impedance matching for high-speed signal lines, thereby reducing signal reflections and improving signal integrity. Moreover, by incorporating the capacitor into the package, the capacitor can be located closer to power and ground connections of the die, thereby reducing a distance between the capacitor and the die, which decreases parasitic inductance and allowing for faster charge delivery. Embedding the capacitor into the package also can curtail power droop by stabilizing voltage levels during transient current demands and reduce electromagnetic interference (EMI) through localized filtering of high-frequency noise.

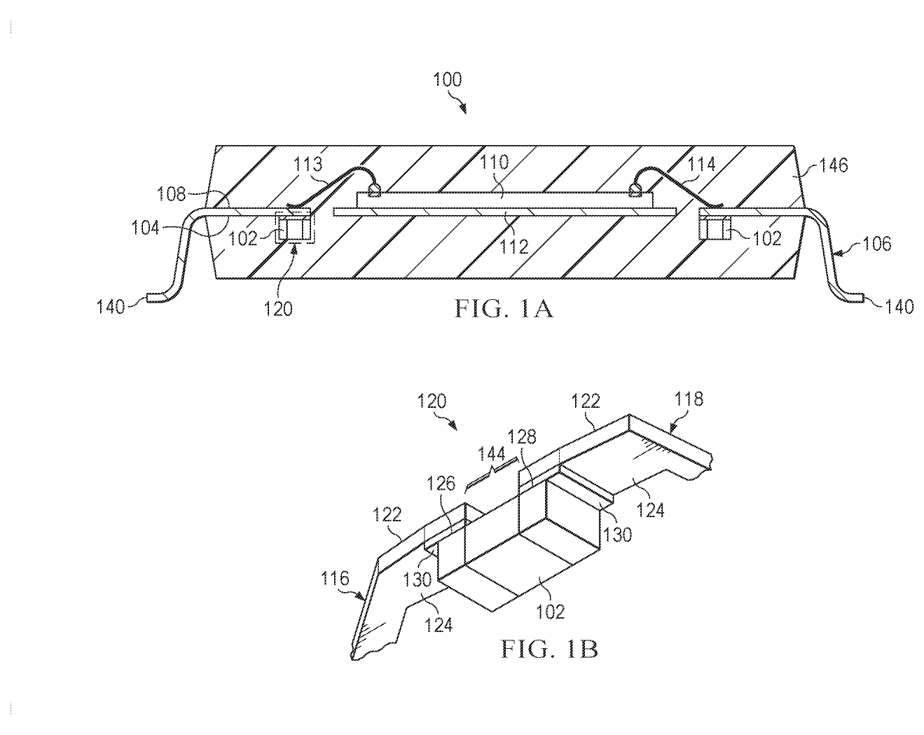

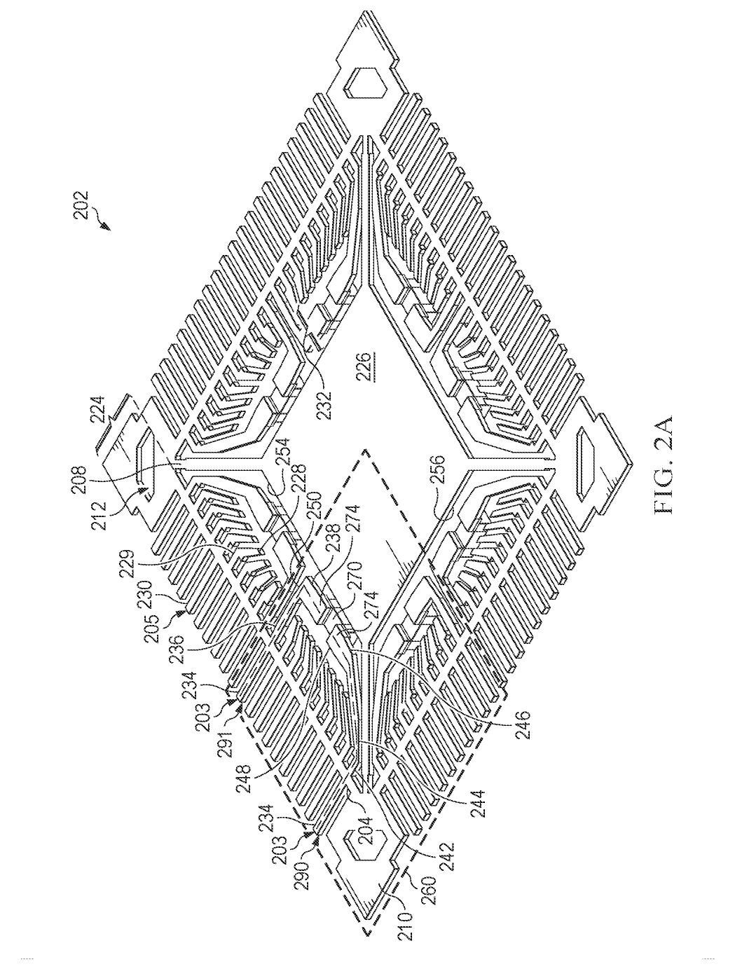

FIG. 1A illustrates a diagram of an example of a semiconductor device 100. In some examples, the semiconductor device 100 is a QFP package. The semiconductor device 100 includes passive components 102 located on a bottom side 104 of a leadframe 106, opposite of a top side 108 of the leadframe 106 on which a die 110 is located. The leadframe 106 includes a die pad 112 that supports the die 110 and multiple lead structures configured to provide electrical connections between the die 110, the passive components 102 and/or external circuitry (e.g., a PCB). The leadframe 106 can be manufactured using an etching or stamping process to form the structural features according to the examples herein.

Each passive component 102 can be coupled to first and second inner lead arms 116-118 of the leadframe 106, as illustrated in FIG. 1B, which is an example illustrating coupling of a first passive component to the first and second inner lead arms 116-118 at an attachment location 120 of the semiconductor device 100 of FIG. 1A. A second passive component of the passive components 102 can be coupled to respective inner lead arms in a same or similar manner as the first passive component. The first and second inner lead arms 116-118 of the leadframe 106 are used for mounting the first passive component while maintaining electrical isolation from adjacent leads. The first and second inner lead arms 116-118 allow for compact integration of the first passive component within the package, reducing the need for external passive components and optimizing PCB layout. For example, the first inner lead arm 116 can extend inward toward the die pad 112 and the second inner lead arm 118 can extend inward toward the die pad 112 but can be spaced apart from the first inner lead arm, defining a terminal isolation gap 144 between the first and second inner lead arms 116-118.

Each of the first and second passive components 102 (e.g., capacitors) includes a first terminal 126 and a second terminal 128, such as illustrated in FIG. 1B. The first terminal 126 can be coupled to a bottom surface 124 of the first inner lead arm 116 via a solder joint 130, while the second terminal 128 can be coupled to a bottom surface 124 of the second inner lead arm 118 via another solder joint 130. The solder joint 130 is used to secure each of the first and second passive components to corresponding inner lead arms, such as the first and second inner lead arms 116-118.

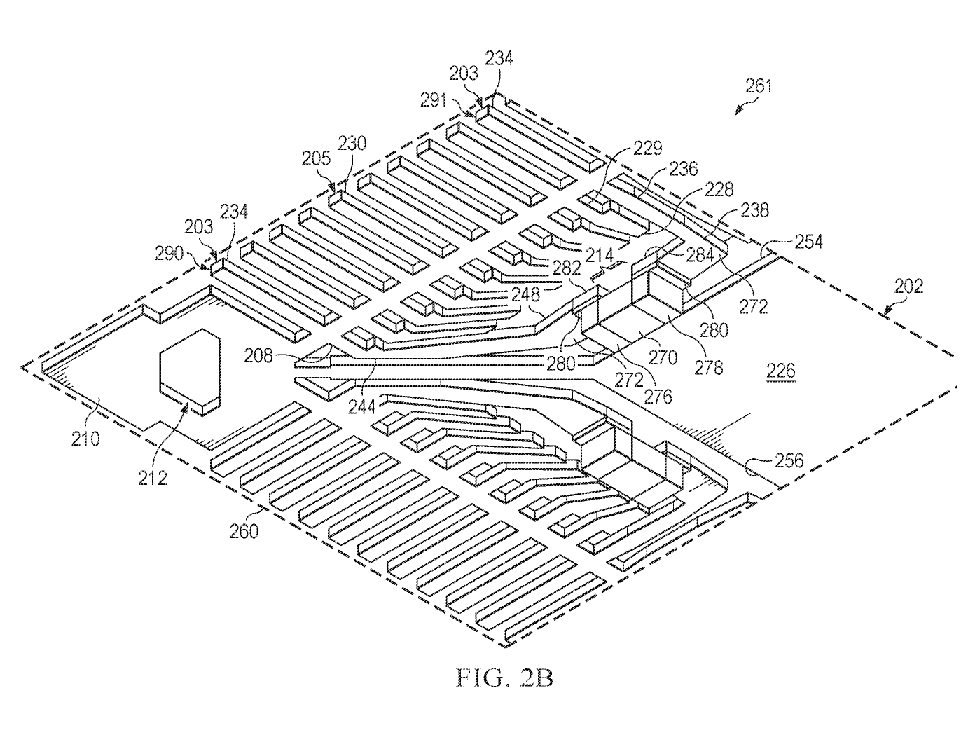

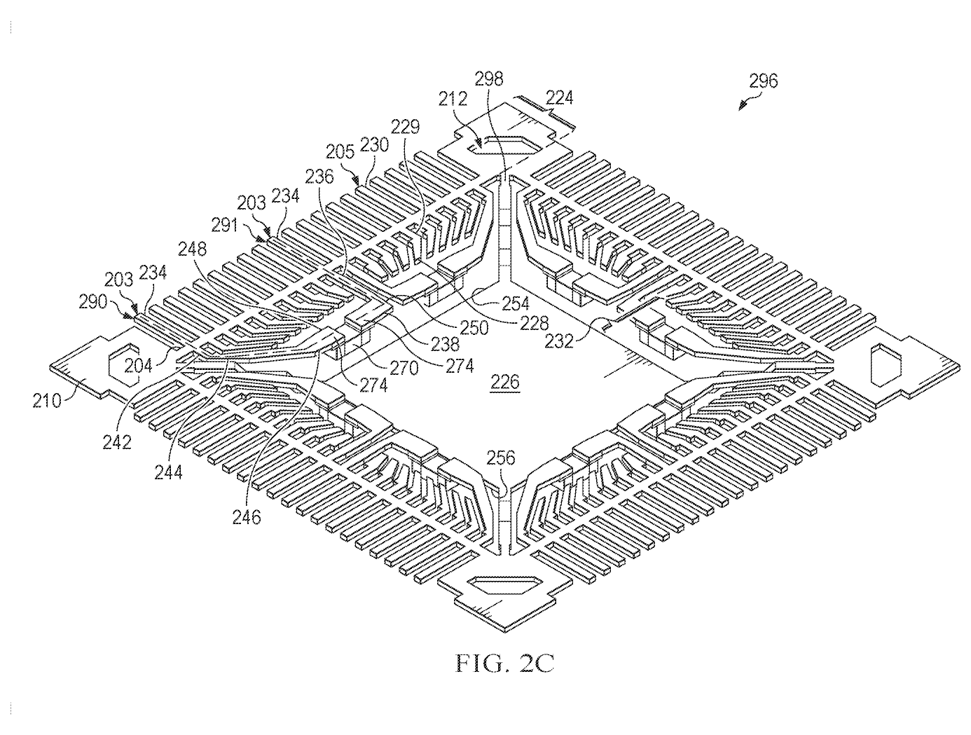

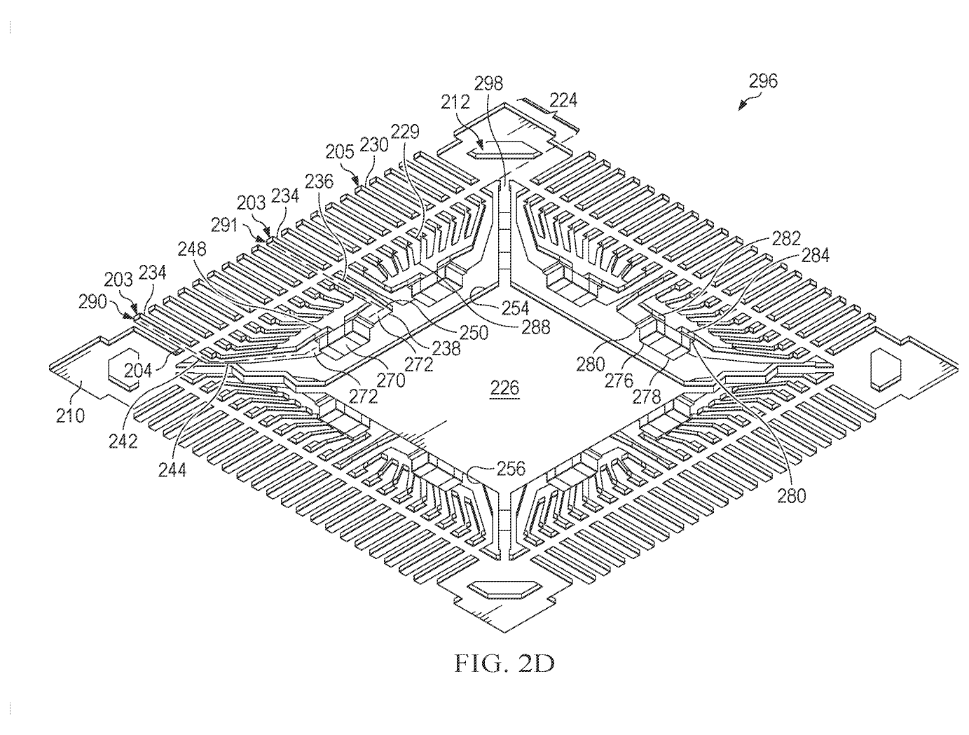

The semiconductor device 100 includes outer lead portions 140, which extend outward from the leadframe 106. In the example of FIG. 1A, the outer lead portions 140 are gull-wing shaped, but can have a different shape in other examples. Each of the first and second inner lead arms 116-118 can be mechanically and electrically coupled to a respective outer lead portion of the outer lead portions 140. The outer lead portions 140 function as external electrical connection points for the semiconductor device 100. For clarity and brevity, two outer lead portions 140 are illustrated; however, in other examples, any number of outer lead portions may be included in the semiconductor device 100, with a subset of outer lead portions of the outer lead portions 140 being electrically and mechanically coupled to inner lead arms. For example, first and second outer lead portions of the subset of outer lead portions can be electrically and mechanically coupled to one of the first and second inner lead arms 116-118. The outer lead portions 140 can also include outer lead portions of connection leads of the leadframe 106, which have been omitted from FIG. 1A for clarity and brevity purposes. Connection leads are lead structures of the leadframe 106 (e.g., such as connection leads 205 of a leadframe 202, as illustrated in FIG. 2A) that can be used for establishing electrical connections between the die 110 and external circuitry (e.g., the PCB). The connection leads extend outward from a periphery or edge of the die 110 of the semiconductor device 100. Each connection lead includes an inner lead portion, which extends toward the die pad 112 and thus an edge of the die 110 and can function as a bonding site for wire bonds to electrically connect a die connection of the die 110 to a corresponding inner lead portion of a connection lead to the leadframe 106. Thus, the inner lead portions of the connection leads can be used for establishing an electrical interface between the die 110 and external circuitry (e.g., the PCB).

In some examples, wire bonds can be used to electrically connect the die 110 to the leadframe 106. For example, a first wire 113 can be used to connect a first die connection of the die 110 to the leadframe 106. A second wire 114 can be used to connect a second die connection of the die 110 to the leadframe 106. In some examples, a first end of the first wire 113 is bonded to a top surface 122 of the first inner lead arm 116 and a second end of the first wire 113 is bonded to a first die connection of the die 110, while a first end of the first second wire 114 is bonded to a top surface 122 of the second inner lead arm 118 and a second end of the second wire 114 is bonded to a second die connection of the die 110. As such, in some examples, wire bonds can be used to establish an electrical path between the die 110 and the passive components 102 (e.g., in some instances for power distribution and noise filtering). In some examples, wire bonds can be used to establish electrical connections between respective die connections of the die 110 and corresponding inner lead portions of connection leads. For example, a wire can be used to connect a given die connection of the die 110 to a respective inner lead portion of a connection lead of the connection leads.

In some examples, the semiconductor device 100 is encapsulated using a molding compound 146, which can encapsulate the die 110, the first and second wires 112-114 and a portion of the leadframe 106, including the first and second inner lead arms 116-118 and the passive components 102. The molding compound 146 is used to shield internal electrical connections from environmental factors, thereby preventing contamination or mechanical damage while allowing the outer lead portions 140 to remain exposed and remain available for external electrical interfacing (e.g., with the PCB).

FIG. 2A illustrates an example of a leadframe assembly 202 that can be used in a manufacturing of the semiconductor device 100, as illustrated in FIG. 1A, and the first and second inner lead arms 116-118 with the first passive component secured thereto, as illustrated in FIG. 1B. In some examples, the leadframe 106 of the semiconductor device 100 is a processed version of the leadframe assembly 202, having undergone passive component attachment and subsequent fabrication steps. FIG. 2A illustrates a perspective view (e.g., a top-side view) of the leadframe assembly 202 while FIG. 2B illustrates a zoomed-in view of a bottom-side portion 261 of the leadframe assembly 202, which is opposite of a top-side portion 260 of the leadframe assembly 202, as illustrated in FIG. 2A. In some examples, the leadframe assembly 202 can correspond to one of multiple leadframe assemblies of a leadframe strip, which can be used in manufacturing of semiconductor devices, such as the semiconductor device 100, as illustrated in FIG. 1A. For example, the leadframe strip can include multiple instances of the leadframe assembly 202, which can be arranged in a linear or matrix format, allowing for batch processing during semiconductor package fabrication. The leadframe strip can be fabricated using etching or stamping techniques as described herein and can undergo processing stages before the leadframe strip is singulated to form individual semiconductor packages.

For example, the leadframe assembly 202 includes carrier pads 210 at respective corners of the leadframe assembly 202. The carrier pads 210 can be used for supporting and stabilizing the leadframe assembly 202 during semiconductor device fabrication. Each carrier pad 210 includes a tool hole 212, which can be used for alignment and handling of the leadframe assembly 202 during semiconductor device fabrication. The leadframe assembly 202 includes tie bars 208, which couple a die pad 226 (e.g., corresponding to the die pad 112 of FIG. 1A) to one of the carrier pads 210, as illustrated in FIG. 2A. The die pad 226 includes a mounting surface for a die, such as the die 110 of the semiconductor device 100 of FIG. 1A. The die pad 226 can lie within a plane of the leadframe assembly 202. The leadframe assembly 202 can extend in two orthogonal directions within this plane, corresponding to an X direction and a Y direction, while a third direction, corresponding to a Z direction, can be perpendicular to the plane of the leadframe assembly 202. The X direction can extend along a first lateral axis, the Y direction can extend along a second lateral axis that is orthogonal to the X direction and the Z direction can extend along a vertical axis that is orthogonal to both the X and Y directions.

The leadframe assembly 202 includes a first set of leads 203 and a second set of leads 205. The first set of leads 203 can be referred to as passive element support leads 203 because these leads are configured to support and electrically interface with one or more passive components within the semiconductor package. The second set of leads 205 can be referred to as connection leads 205 because these leads provide electrical connections between the die and external circuitry without functioning as mounting points for passive components. The connection leads 205 can correspond to the connection leads of the semiconductor device 100, as described herein. Each of the passive element support and connection leads 203-205 can be separated by a dam bar 204, which can span gaps between adjacent leads and also between a lead and a neighboring carrier pad. The dam bars 204 can be used to prevent a mold compound from flowing into spaces between leads during encapsulation. The dam bars 204 can couple adjacent leads during fabrication to provide lead alignment and structural integrity before the passive element support and connection leads 203-205 are separated.

As illustrated in FIG. 2A, outer lead portions 230 of the connection leads 205 extend outward in respective directions of the leadframe assembly 202. In some examples a set of outer lead portions 140 of the semiconductor device 100 of FIG. 1A can include the outer lead portions 230. The outer lead portions 230 function as external electrical connections of the semiconductor device 100. Each connection lead 205 includes an inner lead portion 228, which extends toward the die pad 226 from a transition region 229, where a respective outer lead portion 230 transitions into a corresponding inner lead portion 228. The inner lead portions 228 extend from a periphery portion 224 of the leadframe assembly 202, as illustrated in FIG. 2A. The periphery portion 224 can include the transition region 229 in some instances. At each transition region 229 that couples respective inner and outer lead portions 228-230, each inner lead portion 228 can be angled relative to a direction in which the respective outer lead portion 230 can extend. The inner lead portions 228 can be used for wire bonding and thus provide an accessible bonding surface. The inner lead portions 228 can be separated from the die pad 226 by a die-to-lead separation region 232, as illustrated in FIG. 2A. In some examples, the die-to-lead separation region 232 can be referred to as a gap or a void.

Each inner lead portion 228 of the connection leads 205 can have a thickness that can extend relative to the plane of the leadframe assembly 202, a length that can extend toward the die pad 226 and a width that can extend in a direction relative to the length of the inner lead portion 228. The width of the inner lead portions 228 can be referred to as a bonding width, as a wire is bonded to a surface of each inner lead portion 228 on the top side of the leadframe assembly 202. The outer lead portions 230 can also have a thickness, a length extending outward from the leadframe assembly 202 and a width that can extend along a lateral direction as corresponding inner lead portions. In some examples, the inner lead portions 228 and the outer lead portions 230 can have a substantially similar thickness and width while having different lengths, as illustrated in FIG. 2A. In some examples, the inner and outer lead portions 228-230 have similar lengths.

In some examples, the passive element support leads 203 include passive element support lead pairs, where each pair consists of a first passive element support lead 290 and a second passive element support lead 291 (identified in FIGS. 2A-2B with dashed-lines). By way of example, the description herein relating to FIGS. 2A-2B is presented in with respect to a single respective passive element support lead pair that includes the first and second passive element support leads 290-291, as illustrated in FIGS. 2A-2B. Each passive element support lead pair can be positioned adjacent to the die pad 226 and separated from the die pad 226 by the die-to-lead separation region 232. In the example illustrated in FIG. 2A, eight passive element support lead pairs are positioned adjacent to the die pad 226. In some examples, the leadframe assembly 202 can include fewer passive element support lead pairs.

Continuing with the example of FIGS. 2A-2B, in some instances, the first passive element support lead 290 can be located adjacent to (or neighbor) a respective carrier pad 210. The first passive element support lead 290 includes an outer lead portion 234, which can be similar in structure to the outer lead portion 230 of the connection lead 205. Outer lead portions 234 of the passive element support leads 203 and outer lead portions 230 of the connections leads 205 can extend in a same or similar direction with respect to the die pad 226 (e.g., away from the die pad 226, as illustrated in FIGS. 2A-2B). By way of further example, the second passive element support lead 291 can be positioned at a predefined spacing (or location) from the first passive element support lead 290 along the periphery portion 224, with a number of connection leads interposed between the first and second passive element support leads 290-291.

For example, the first passive element support lead 290 includes a first inner lead arm, which can correspond to the first inner lead arm 116 of FIG. 1B. The first inner lead arm can be defined by a first transition region 242, a first intermediate segment 244, the second transition region 246 and a first terminal segment 248 of the leadframe assembly 202. As illustrated in FIG. 2A, the first inner lead arm can have a first portion (e.g., the first intermediate segment 244) that is wider than a second portion (e.g., the first terminal segment 248). The first intermediate segment 244 can extend from the first transition region 242, where the outer lead portion 234 transitions to the first intermediate segment 244. The first intermediate segment 244 can extend at an angle relative to the outer lead portion 234, extending away from the carrier pad 210 and inward toward a periphery of the die pad 226 (e.g., toward an edge 254 of the die pad 226, as illustrated in FIG. 2A). The first terminal segment 248 can extend from the second transition region 246, where the first intermediate segment 244 transitions to the first terminal segment 248. The first terminal segment 248 extends about parallel with respect to a corresponding edge of the die pad 226 (e.g., the edge 254 of the die pad 226). In some examples, the first terminal segment 248 is about perpendicular to the edge 256 of the die pad 226, as illustrated in FIGS. 2A-2B.

For example, the second passive element support lead 291 includes a second inner lead arm, which can correspond to the second inner lead arm 118 of FIG. 1B. The second inner lead arm can be defined by a second intermediate segment 236, a third transition region 250 and a second terminal segment 238 of the leadframe assembly 202. As illustrated in FIG. 2A, the second inner lead arm can have a first portion (e.g., the second intermediate segment 236) that is wider than a second portion (e.g., the second terminal segment 238). The second intermediate segment 236 can be substantially parallel to the outer lead portion 234 (e.g., extend in a same direction or about perpendicular relative to the edge 254 of the die pad 226). The second terminal segment 238 can extend from the third transition region 250, where the second intermediate segment 236 transitions to the second terminal segment 238. The second terminal segment 238 can be about perpendicular to the edge 256 of the die pad 226, as illustrated in FIGS. 2A-2B. The second intermediate segment 236 can extend in a direction substantially similar to the outer lead portion 234 and thus can follow about a same longitudinal axis before transitioning at the third transition region 250 to the second terminal segment 238. Accordingly, the first and second terminal segments 238, 248, which can be thicker than the first and second intermediate segments 244, 236 can run parallel to the edge 254 of the die pad 226. The first and second terminal segments 238, 248 can be positioned (or located) within the die-to-lead separation region 232, spaced apart from the edge 254 of the die pad 226 and corresponding inner lead portions 228 of respective connection leads 205, as illustrated in FIGS. 2A-2B.

In some examples, each outer lead portion 234 of the passive element support leads 203 can have substantially a same thickness, width and length as the outer lead portion 230 of the connection leads 205. In yet some examples, the first intermediate segment 244 and the second intermediate segment 236 can have substantially a same thickness and width, but, in some instances, can have different respective lengths. The first terminal segment 248 and the second terminal segment 238 can have about a same thickness and/or width. In some examples, the first and second terminal segments 248, 238 can have same or similar lengths.

By way of further example, the first terminal segment 248 and the second terminal segment 238 can have a different width than the width of the first intermediate segment 244, the second intermediate segment 236 and/or the outer lead portions 230 and 234. The width of the first terminal segment 248 and the second terminal segment 238 can be referred to as a passive bonding width, as a passive element, such as a capacitor 270 (e.g., corresponding to one of the passive elements 102, as illustrated in FIGS. 1A-1B) is bonded to a bottom surface 272 of each of these terminal segments, as illustrated in FIGS. 2A-2B. In some examples, the width of the first and second terminal segments 236-248 can be substantially similar to or greater than a width of a body of the capacitor 270 bonded to these lead portions, providing sufficient contact area for electrical and mechanical stability for the capacitor 270. Each of the first and second terminal segments 248, 238 has a bottom surface 272 that functions as a bonding interface for the capacitor 270 and an opposing top surface 274, which can remain exposed on the top-side of the leadframe assembly 202, as illustrated in FIG. 2A.

For example, the capacitor 270 can be electrically and mechanically coupled to corresponding bottom surfaces 272 of the first and second terminal segments 248, 238 on the bottom side of the leadframe assembly 202, as illustrated in FIG. 2B. The capacitor 270 can be coupled to the bottom surfaces 272 using a solder joint 280. The capacitor 270 includes two opposing terminals, where a first terminal 276 of the capacitor 270 is bonded by the solder joint 280 to the bottom surface 272 of the first terminal segment 248. A second terminal 278 of the capacitor 270 is bonded to the bottom surface 272 of the second terminal segment 238. The first and second terminals 276-278 of the capacitor 270 can correspond to metallized end caps or pads located at opposite ends of the body of the capacitor 270. The end pads of the capacitor 270 can be referred to as landing pads in some instances.

Each of the first and second terminals 276 and 278 of the capacitor 270 can have a length (also can be referred to as a landing pad length) that can extend along a longitudinal axis of the body of the capacitor 270, corresponding to a distance between first and second terminal edges of the capacitor 270. The landing pad length can match or exceed a contact area (e.g., an end portion such as first or second end portions 282-284, as illustrated in FIG. 2A) of the bottom surfaces 272 of the first and second terminal segments 248, 238. In some examples, a width (also can be referred to as a landing pad width) of each landing pad can extend across a lateral dimension of the body of the capacitor 270. The landing pad width can be substantially equal to or slightly smaller than the width of the first and second terminal segments 248 and 238.

In some examples, the width of the first terminal segment 248 and the second terminal segment 238 can be based on the landing pad width of the capacitor 270 to provide sufficient electrical and mechanical coupling. For example, the width of each of the first and second terminal segments 248, 238 can be dimensioned to provide a bonding interface for the corresponding landing pads (e.g., the first and second terminals 276-278) of the capacitor 270. In some implementations, the width of the first and second terminal segments 248, 238 can be equal to or slightly greater than the landing pad width of the capacitor 270 to maximize a contact area between the first and second terminals 276-278 and the leadframe assembly 202. Such a configuration can be used to increase solder joint reliability by promoting uniform solder wetting across the bonding surfaces. A larger lead portion width relative to a landing pad width of the capacitor 270 can further reduce electrical resistance at the connection interface, thereby improving signal integrity and thermal dissipation. In some instances, where space constraints or specific electrical properties may be desired, the first and second terminal segments 248, 238 can have a width that can be proportional to the landing pad width of the capacitor 270 to increase solder coverage while curtailing overhang or misalignment. Thus, the leadframe assembly 202 can be produced with the first and second terminal segments 248, 238 that can accommodate variations in capacitor sizes of the capacitor 270. In some examples, the capacitor 270 is a ceramic capacitor, such as a multilayer ceramic capacitor (MLCC). Accordingly, by setting the width of the first and second terminals segments 248, 238 based on the landing pad width of the capacitor 270, the capacitor 270 can be secured to the leadframe assembly 202 with minimal to no impact on electrical performance.

In some examples, the first terminal segment 248 and the second terminal segment 238 can be positioned such that respective ends of these terminal segments face each other (in opposite directions) but remain separated by a terminal isolation gap 214, as illustrated in FIG. 2B. The terminal isolation gap 214 electrically isolates the first terminal segment 248 and the second terminal segment 238, thereby preventing unintended shorting between these segments while accommodating the placement of the capacitor 270. The terminal isolation gap 214 extends between a first end portion 282 of the first terminal segment 248 and a second end portion 284 of the second terminal segment 238. As illustrated in FIG. 2B, the capacitor 270 can be coupled to the bottom surfaces 272 of the first end and second portions 282-284. In some examples, a width of the terminal isolation gap 214 can be dimensioned based on a width of the capacitor 270, such that the capacitor 270 can be positioned over the terminal isolation gap 214 so that the first and second terminals 276-278 of the capacitor 270 rest on the solder joint 280 at corresponding first and second end portions 282-284, respectively. In some examples, the terminal isolation gap 214 can have a width that is slightly greater than or approximately equal to the width of the capacitor 270. The length of the terminal isolation gap 214 can extend along a direction between the first end portion 282 and the second end portion 284, corresponding to a terminal segment separation distance between the first and second terminal segments 248, 238. In some examples, the length of the terminal isolation gap 214 between ends of the first and second terminal segments 248, 238 can be based on a spacing needed for capacitor placement (e.g., a length of the capacitor 270). Accordingly, the terminal isolation gap 214 separates two terminal segments of the capacitor 270, each being sized with a width to accommodate terminals of the capacitor 270, whereas other portions of the passive element support leads 203 (e.g., as described herein) can have a smaller width.

FIGS. 2C-2D illustrates another example of a leadframe assembly 296 that can be used in manufacturing of the semiconductor device 100 of FIG. 1A, similar to the leadframe assembly 202 of FIGS. 2A-2B. In some examples, the leadframe 106 of the semiconductor device 100 is a processed version of the leadframe assembly 296, having undergone passive component attachment and subsequent fabrication steps. For clarity and consistency, similar reference numerals are used in the description with respect FIGS. 2C-2D as used in connection with FIGS. 2A-2B, otherwise as noted herein. FIG. 2C illustrates a top-side view of the leadframe assembly 296, while FIG. 2D illustrates a bottom-side view of the leadframe assembly 296, which is opposite to the top-side view of FIG. 2C.

In FIGS. 2C-2D, the tie bars 298 that couple the die pad 226 to the leadframe assembly 296 extend at an angle rather than lying substantially in plane with the die pad 226, as in FIGS. 2A-2B. This angular orientation of the tie bars 298 positions the die pad 226 at a lower vertical level relative to the periphery portion 224 of the leadframe assembly 296, where inner and outer lead portions of the passive element support leads 290-291 and the connection leads 205 are located. As a result, the first and second passive element support leads 290-291 extend laterally toward the die pad 226 from an elevated position within the leadframe assembly 296, such that inner lead arms of these support leads are positioned at a higher vertical level than the die pad 226. This stepped configuration introduces a vertical separation between the die pad 226 and the inner lead arms of the passive element support leads 290-291, as illustrated in FIGS. 2C-2D.

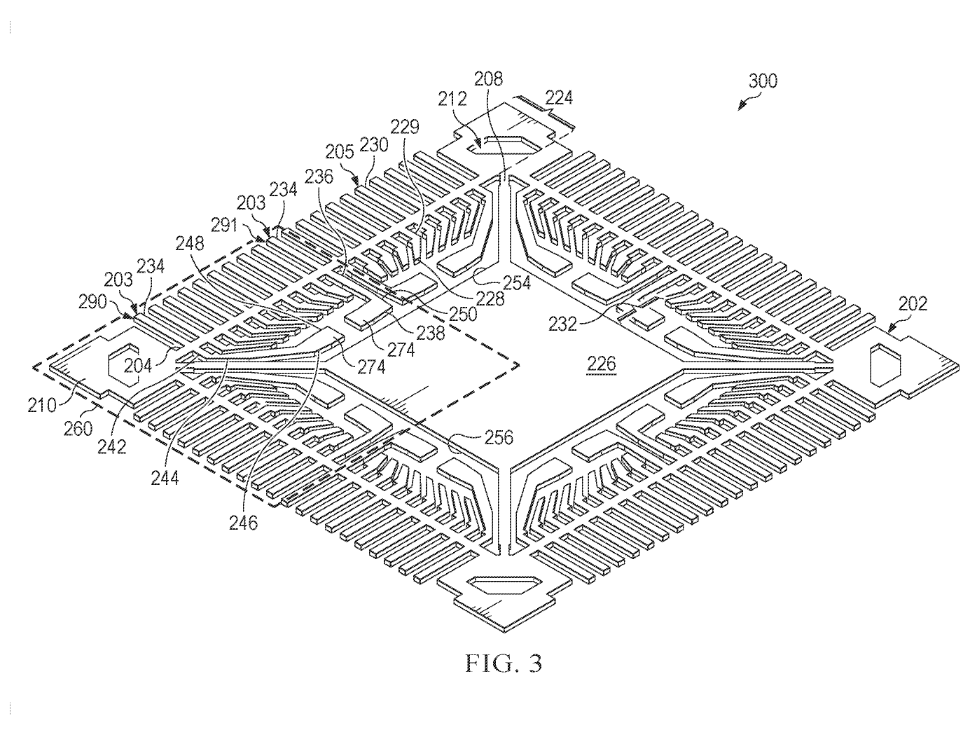

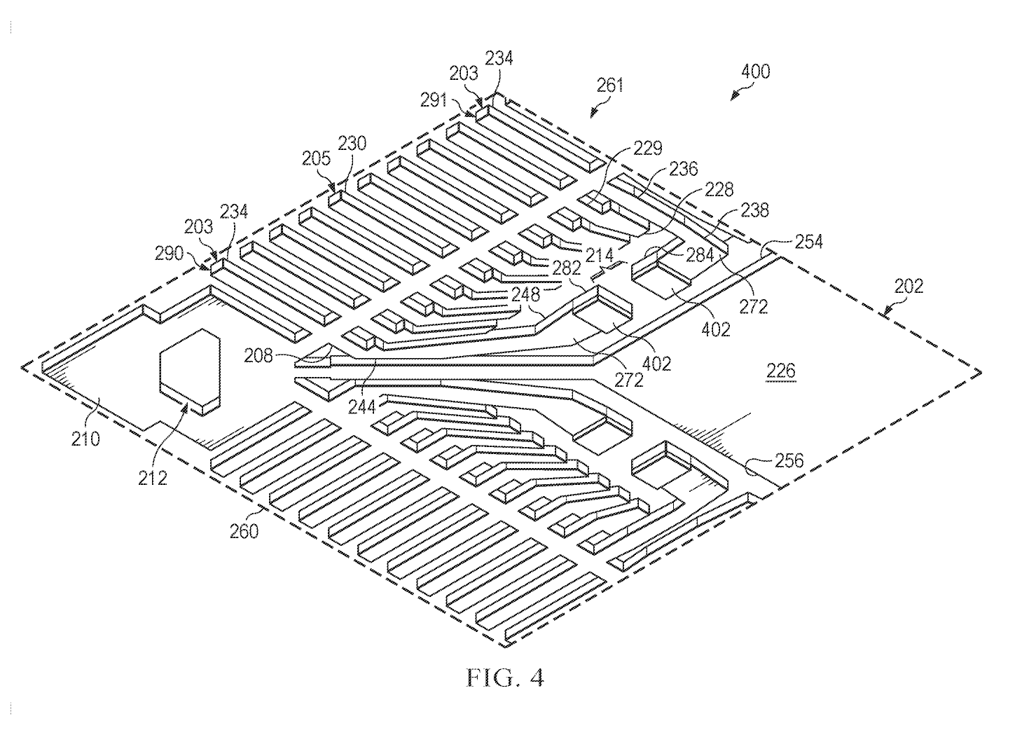

FIGS. 3-10 illustrate stages of a method for fabricating (e.g., assembling) a semiconductor device, such as the semiconductor device 100 of FIG. 1A. The method can begin at a first stage 300, at which a leadframe assembly 302 can be provided or retrieved. In some examples, the leadframe assembly 302 is part of a leadframe strip that includes multiple instances of the leadframe assembly 302. In some examples, the leadframe assembly 302 and thus the leadframe strip is produced at the first stage 300. The leadframe assembly 302 can correspond to the leadframe assembly 202 of FIGS. 2A-2B (or in other instances to the leadframe assembly 296 of FIGS. 2C-2D), without passive components, such as capacitors, including the capacitor 270, as illustrated in FIGS. 2A-2B (or FIGS. 2C-2D). Thus, for clarity and brevity purposes similar reference numerals are used in the example method of FIGS. 3-10 as used in the example of FIGS. 2A-2D. The description of the method with respect to FIGS. 3-10 is provided with respect to a single leadframe assembly. However, in examples in which the leadframe strip is used, same or similar stages (or operations) can be performed simultaneously, in sequence, or in parallel across multiple leadframe assemblies of the leadframe strip to produce respective semiconductor packages similar to the semiconductor device 100 of FIG. 1A.

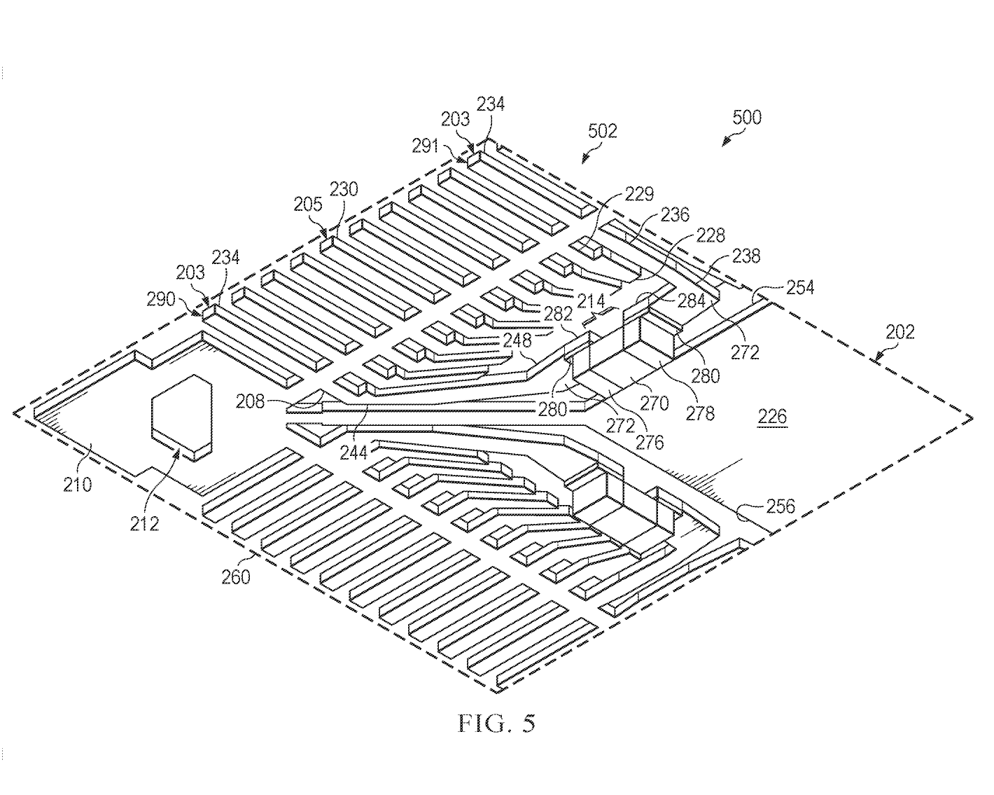

For example, at a second stage 400, a solder 402 (e.g., a solder paste) can be placed on the bottom surfaces 272 of the first and second terminal segments 248, 238 on the bottom-side of the leadframe assembly 202, as illustrated in FIG. 4. In some examples, at the second stage 400, the leadframe assembly 202 can be flipped for soldering placement. FIG. 3 corresponds to a perspective view (e.g., a top-side view) of the leadframe assembly 202. FIG. 4 illustrates a zoomed-in view of the bottom-side portion 261 of the leadframe assembly 202, which is opposite of the top-side portion 261, as illustrated in FIG. 3. For example, the solder 402 can be applied to the bottom surface 272 at the first end portion 282 of the first terminal segment 248 and the solder 402 can be applied to the bottom surface 272 at the second end portion 284 of the second terminal segment 238.

In yet some examples, before placing the solder 402 a stencil can be aligned on the bottom-side of the leadframe assembly 202 with cut-out openings that match locations of the first and second end portions 282-284. The stencil can then be lifted, leaving controlled solder paste deposits on the bottom surfaces 272 at the first and second end portions 282-284, as illustrated in FIG. 4. In some examples in which the leadframe strip is used, solder 402 can be applied across all leadframe assemblies of the leadframe strip. For example, a stencil can be aligned on a bottom side of the leadframe strip, with cut-out openings corresponding to locations of the first and second end portions 282-284 of each leadframe assembly of the leadframe strip. The solder 402 can be spread across the stencil to fill the cut-out openings over the first and second end portions 282-284 of each leadframe assembly. The stencil can then be lifted, leaving controlled solder paste deposits on the bottom surfaces 272 of the first and second end portions 282-284, as illustrated in FIG. 4.

At a third stage 500, a passive element attachment process can be implemented. One or more passive components, such as the capacitor 270 (or one or more passive components similar to the passive components 102 of FIG. 1A), can be secured to each leadframe assembly of the leadframe strip including the leadframe assembly 202 (or the leadframe assembly 296), in some instances, in a parallel batch process. For example, the first and second terminals 276-278 of the capacitor 270 can be oriented (or aligned) with solder deposits on the first and second end portions 282-284 and positioned over the terminal isolation gap 214 so that each of the first and second terminals 276-278 of the capacitor 270 contacts the solder 402. A pick-and-place machine can be used to position the capacitor 270. Once each capacitor 270 is positioned (e.g., the first and second terminals 276-278 are sitting or resting on the solder 402 at one of the first and second end portions 282-284), this assembly can undergo reflow soldering to bond the first and second terminals 276-278 to one of the first and second end portions 282-284, resulting in an intermediate structure 502, as illustrated in FIG. 5. The solder 402 deposited at the first and second end portions 282-284 solidifies into the solder joints 280, as illustrated in FIG. 5. FIG. 5 illustrates a zoomed-in view of the bottom-side portion 261 of the leadframe assembly 202.

In some examples, the passive element attachment process can be repeated for any number of passive components (e.g., capacitors, resistors, inductors, diodes, etc.) that need to be attached to the leadframe assembly 202. Thus, in some examples, each passive element can be attached to a pair of passive element support leads, such as the first and second passive element support leads 290-291. The first and second passive element support leads 290-291 include bonding surfaces for securing a passive component to the leadframe assembly 202, such as the capacitor 270. In some examples in which the leadframe strip is used, reflow soldering can be performed across all leadframe assemblies of the leadframe strip, allowing for multiple passive components to be attached to corresponding leadframe assemblies. The solder 402 deposited at the first and second end portions 282-284 of each leadframe assembly solidifies into the solder joints 280, as illustrated in FIG. 5.

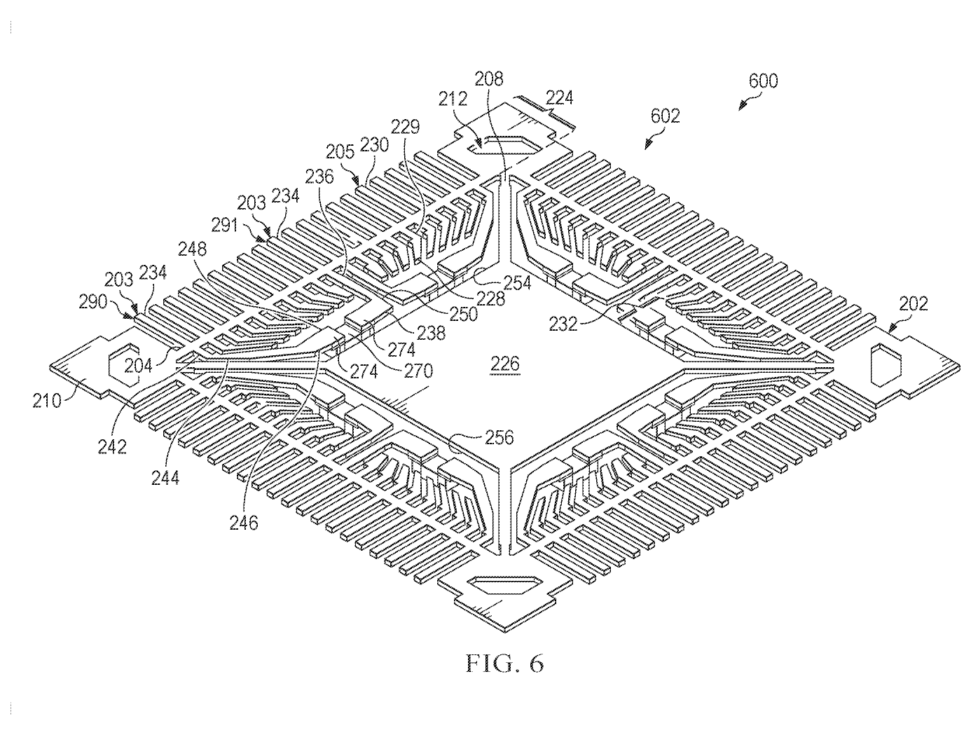

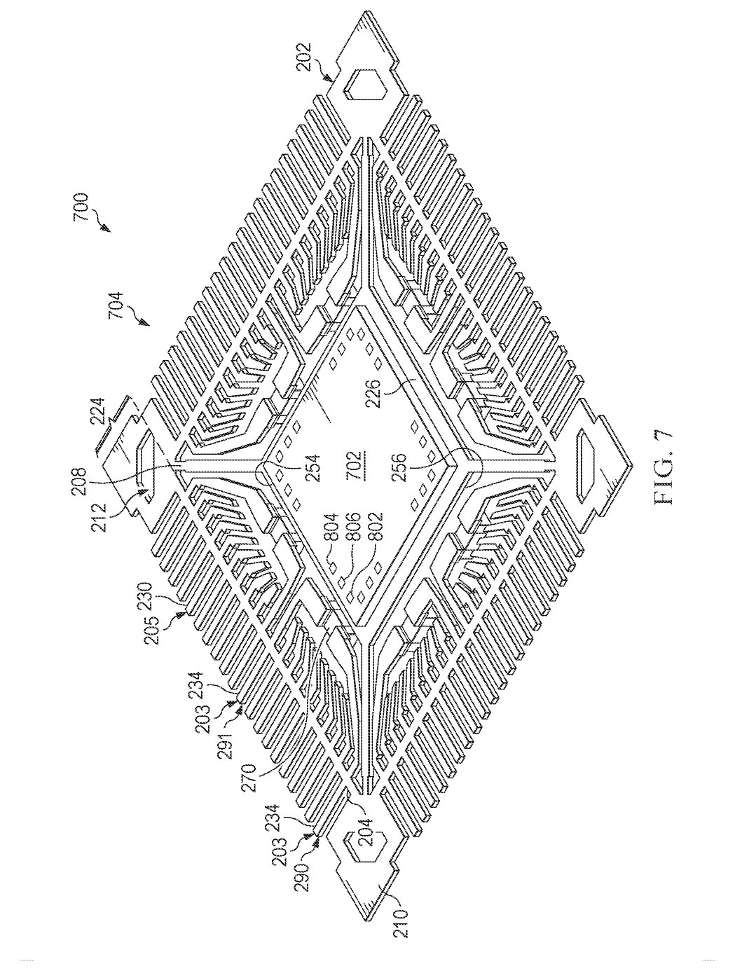

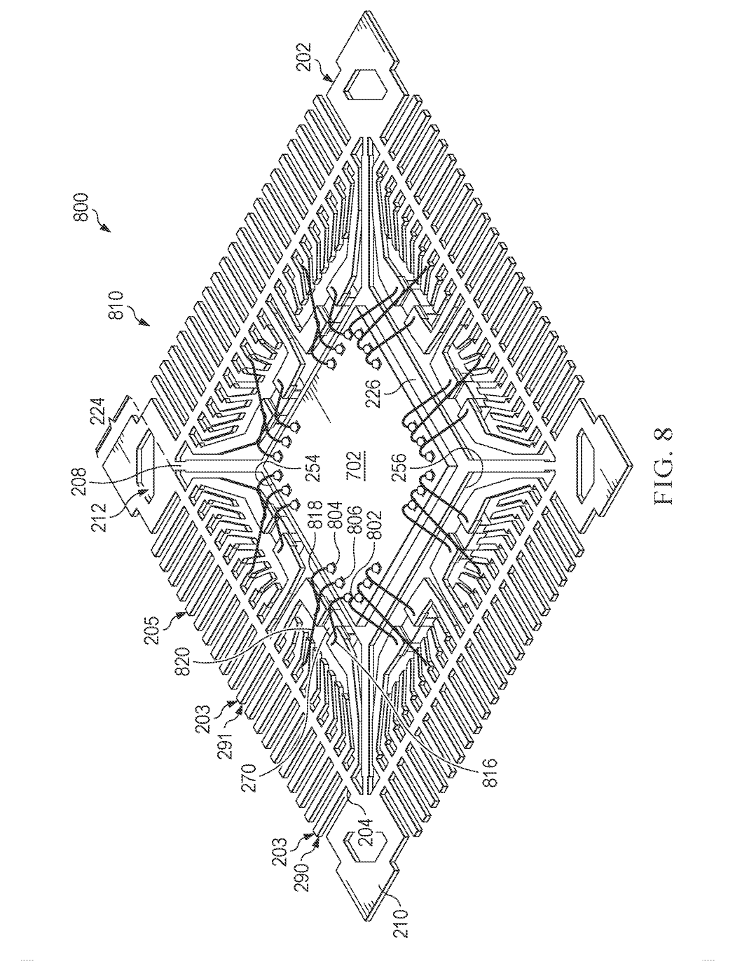

In some examples, the method proceeds to a fourth stage 600 at which the leadframe assembly 202 is flipped, resulting in a leadframe assembly 602, as illustrated in FIG. 6. In yet other examples, the fourth stage 600 can be omitted and the method can proceed to a fifth stage 700. For example, the method can proceed to a fifth stage 700, at which a die 702 (e.g., corresponding to the die 110 of FIG. 1) can be attached to the leadframe assembly 202. The die 702 can be attached to the die pad 226 of the leadframe assembly 202. For example, at the fifth stage 700, the die 702 can be attached to the die pad 226 of the leadframe assembly 202 using a die attach process. This process can include applying a die attach material, such as adhesive epoxy, conductive paste, or solder, onto the die pad 226. The die 702 can be placed onto the die pad 226. Once positioned, the leadframe assembly 602 with the die 702 can undergo a curing or reflow process, depending on a type of die attach material used, to secure the die 702 to the leadframe assembly 202 to provide a die-attached leadframe assembly 704, as illustrated in FIG. 7. This attachment provides mechanical stability and thermal dissipation, facilitating subsequent wire bonding and packaging steps. In some examples in which the leadframe strip is used, multiple dies can be attached to respective leadframe assemblies of the leadframe strip, in some instances, in parallel using batch die attach processes.

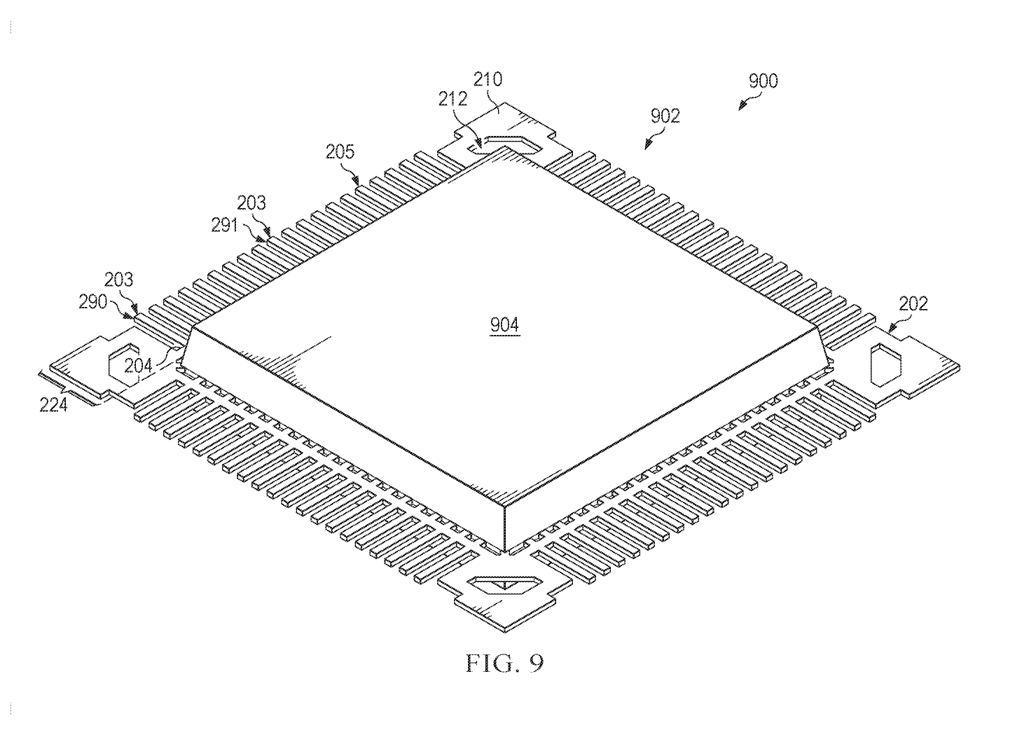

At a sixth stage 800, a wire bonding process can be performed to establish electrical connections between the die 702 and the die-attached leadframe assembly 704, resulting in a wire-bonded leadframe assembly 810, as illustrated in FIG. 8. In some examples in which the leadframe strip is used, a batch wire bonding process can be performed across all leadframe assemblies of the leadframe strip to form respective electrical connections between a corresponding die and leadframe assembly. Wire bonding can be used to form electrical interconnections between die connections (also known in some instances as die pads) of the die 702 and corresponding inner lead portions of the leadframe assembly 202, such as the inner lead portions 228 and/or the first and second terminal segments 248, 238. In some examples, a first wire 816 can be used to form a first wire bond between a first die connection 802 of the die 702 and the top surface 274 of the first terminal segment 248. As an example, a first end of the first wire (e.g., gold (Au), aluminum (Al), or copper (Cu)) 816 can be placed onto the first die connection 802 and ultrasonic, thermosonic, or thermocompression bonding can be used secure the first end of the first wire 816 to the first die connection 802. A second end of the first wire 816 can be secured to the top surface 274 of the first terminal segment 248 in same or similar manner as the first end of the wire. In some examples, a second wire bond can be formed between a second die connection 804 of the die 702 and the second terminal segment 238 using a second wire 818. In yet further examples, a third wire bond can be formed between a third die connection 806 of the die 702 and a corresponding inner lead portion 228 of a respective connection lead 205 using a third wire 220. The second and third wire bonds can be formed in a same or similar manner as the first wire bond is formed, as described herein. The wire bonding process can be repeated as needed to form connections between additional die connections of the die 702 and corresponding lead portions of the leadframe assembly 202, including additional terminal segments and/or inner lead portions of the connection leads 205.

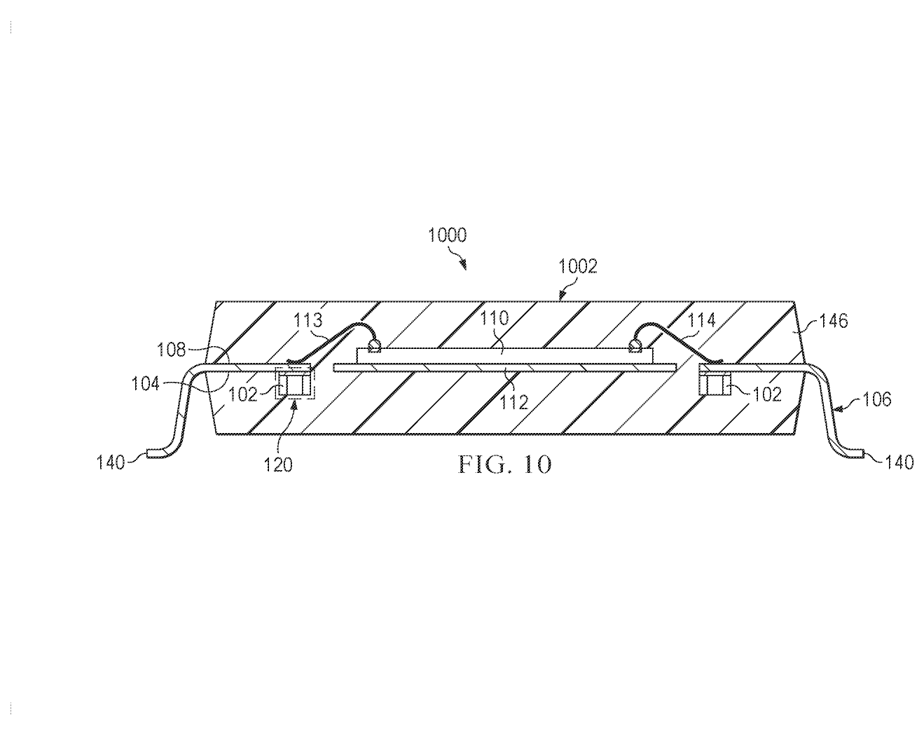

For example, at a seventh stage 900, an encapsulation process is performed to apply a mold compound 904 around portions of the wire-bonded leadframe assembly 810, resulting in an encapsulated leadframe assembly 902, as illustrated in FIG. 9. The encapsulation process is used to protect the die 702, wire bonds and passive components, such as the capacitor 270, while allowing regions of the leadframe assembly 202 to remain exposed to facilitate electrical connectivity and subsequent processing steps. For example, during the encapsulation process, a mold compound, such as an epoxy-based thermoset resin, can be introduced into a mold cavity under controlled pressure and temperature conditions. The mold compound flows around predefined portions of the wire-bonded leadframe assembly 810, covering at least partially both the top and bottom sides of the wire-bonded leadframe assembly 810, while leaving the outer lead portions 234 of the passive element support leads 203, the outer lead portions 234 of the connection leads 205 and the dam bars 204 therebetween exposed. The carrier pads 210 can also remain uncovered (e.g., to support alignment, handling and/or singulation operations). Upon completion of a molding stage, a curing process can be applied to harden the mold compound 904, resulting in the encapsulated leadframe assembly 902, as illustrated in FIG. 9. In some examples in which the leadframe strip is used, the encapsulation process is performed across the leadframe strip, allowing leadframe assemblies of the leadframe strip to be encapsulated.

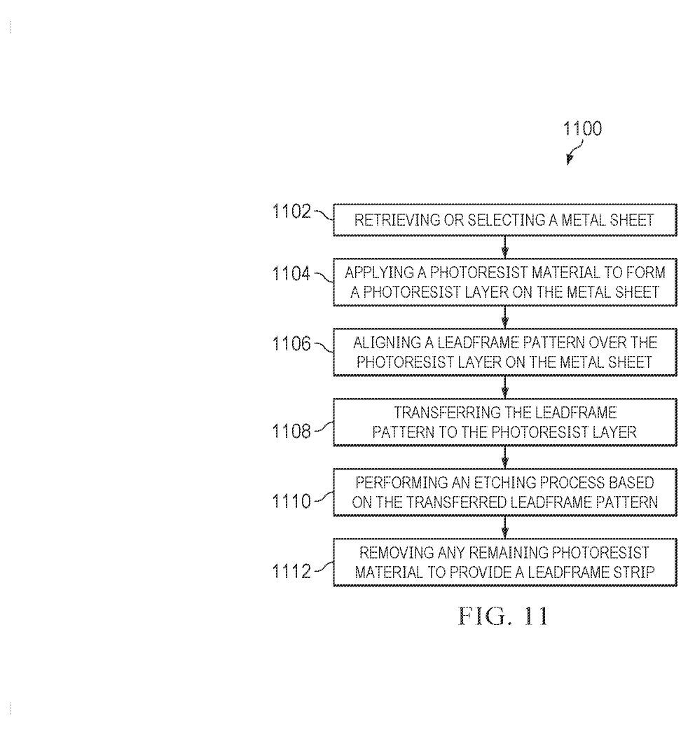

At an eighth stage 1000, trimming and lead forming operations can be performed on the encapsulated leadframe assembly 902, resulting in a semiconductor device 1002, as illustrated in FIG. 10. The semiconductor device 1002 can correspond to the semiconductor device 100, as illustrated in FIG. 1A. For example, at the eighth stage 1000, following the encapsulation process, a first trimming operation can be performed to remove the dam bars 204 that temporarily connected adjacent leads during fabrication. The dam bars 204 are cut away to electrically isolate individual leads, ensuring that adjacent passive element support and connection leads 203-205 are no longer connected by the dam bars 204. A lead forming operation can be performed to shape the outer lead portions 230, 234 of the passive element support and connection leads 203-205, respectively, into a predetermined configuration that facilitates surface mounting or through-hole insertion. The lead forming process can include bending the outer lead portions 230, 234 at desired angles to achieve a desired lead profile. The specific lead configuration can vary based on package factors, with leads being formed into gull-wing, J-lead, or other suitable shapes to allow for mounting on a PCB or other substrate. The encapsulated leadframe assembly 902 remains held in place by the carrier pads 210 and tool holes 212 during the lead forming process. Once lead forming is complete, a trimming operation can be performed to remove the carrier pads 210, resulting in the semiconductor device 1002, as illustrated in FIG. 10. In some examples in which the leadframe strip is used, trimming and lead forming can be performed on multiple encapsulated leadframe assemblies of the leadframe strip, with singulation being performed to provide individual semiconductor packages similar to the semiconductor device 100 of FIG. 1A.

FIG. 11 is an example of a method 1100 of manufacturing a leadframe strip that includes the leadframe assembly 202 of FIGS. 2A-2B or the leadframe assembly 296 of FIGS. 2C-2D. The leadframe strip can include multiple instances of the leadframe assembly 202, 296 and can be fabricated using an etching technique. According to the examples herein, the leadframe strip can be manufactured such that each leadframe assembly includes the first and second passive element support leads 290-291 of FIGS. 2A-2D, thereby providing bonding surfaces (e.g., the bottom surfaces 272) for attaching a passive element (e.g., the capacitor 270) during semiconductor package fabrication, as described herein.

At block 1102, the method 1100 can begin with retrieval or selection of a metal sheet, such as a copper or copper alloy (e.g., Cu-Fe, Cu-Ni-Sn, etc.). At block 1104, a photoresist material can be applied to one or more sides of the metal sheet to form a photoresist layer to allow for selective metal material removal during an etching process. The photoresist layer serves as a protective coating that undergoes patterning to define structural features of the leadframe strip, including each leadframe assembly 202, 296.

At block 1106, a photomask (or mask plate) is aligned over a surface (e.g., a top surface) of the metal sheet with the applied photoresist layer. The photomask includes a leadframe pattern, which defines specific areas of the photoresist that can be exposed to ultraviolet (UV) light and areas that will be shielded. The photomask thus defines a structural layout of the leadframe strip, enabling selective metal removal to form leadframe features, including passive element support and connection leads 203-205, as illustrated in FIGS. 2A-2D. The leadframe pattern specifies a geometric design of conductive metal features within the leadframe strip, including an arrangement, shape and dimensions of each leadframe assembly.

For example, the leadframe pattern includes a connection lead layout that defines the inner lead portions 228 and the outer lead portions 230 and thus the connection leads 205, as illustrated in FIGS. 2A-2D. The leadframe pattern can include a passive element support lead layout that defines the first intermediate segment 244 and the second intermediate segment 236, as illustrated in FIGS. 2A-2D. The passive element support lead layout further includes the first terminal segment 248 and the second terminal segment 238, which can be dimensioned to allow for passive component attachment, as described herein. Additionally, the leadframe pattern includes a die pad layout that defines the die pad 226, a tie bar layout that defines the tie bars 208 (or the tie bars 298) and a dam bar layout that defines the dam bars 204, as illustrated in FIGS. 2A-2B or 2C-2D. In some examples, the leadframe pattern further includes a carrier pad layout that defines each of the carrier pads 210, as illustrated in FIGS. 2A-2D.

At block 1106, the method includes transferring the leadframe pattern onto the photoresist layer. Photolithography can be used to transfer the leadframe pattern to the photoresist layer. Once the photomask (the leadframe pattern) is aligned, UV light can be directed through transparent regions of the mask, exposing corresponding areas of the photoresist layer. In one example, for a positive photoresist, exposed areas can undergo chemical degradation, making the exposed areas soluble in a developer solution. In another example, for a negative photoresist, exposed areas can undergo polymerization, making the exposed areas insoluble in the developer solution while the unexposed areas are dissolved away.

At block 1108, an etching process can be performed to selectively remove metal from the exposed regions of the metal sheet based on the transferred leadframe pattern, forming structural features of the leadframe strip, such as structural features of the leadframe assembly 202, as illustrated in FIGS. 2A-2B, or the leadframe assembly 296, as illustrated in FIGS. 2C-2D. The etching process removes material in areas where the photoresist material was developed away, while a remaining photoresist protects unetched regions of the leadframe pattern. A type of etching that can be used includes a wet chemical etching process or a dry (plasma) etching process. In some examples, after etching is completed, the method can proceed to block 1112, where any remaining photoresist layer can be removed, resulting in a leadframe strip. The leadframe strip includes multiple instances of the leadframe assembly 202 (or the leadframe assembly 296), each configured for use in semiconductor package fabrication, as described herein. In some examples, the leadframe strip can undergo a cleaning process to remove residual etchant. In yet some examples, surface plating can be applied to enhance solderability and oxidation resistance of the leadframe strip.

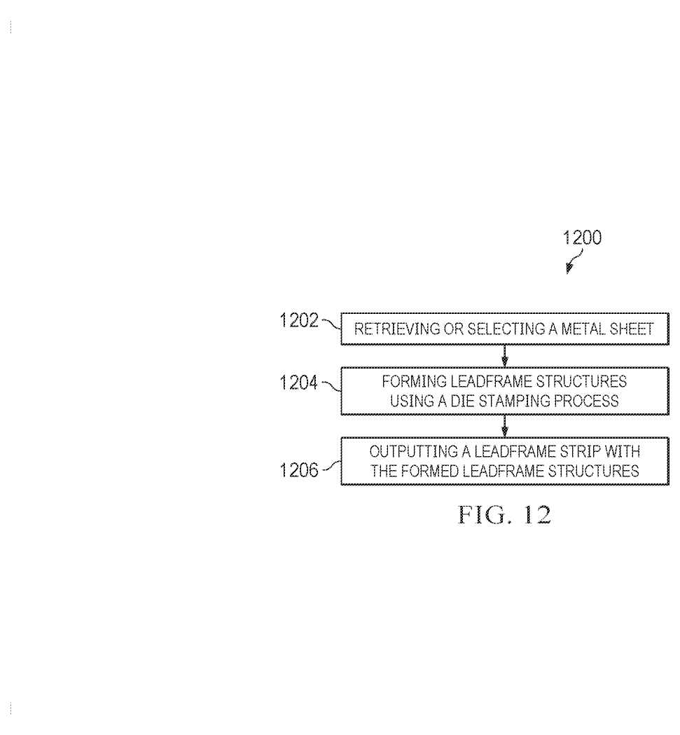

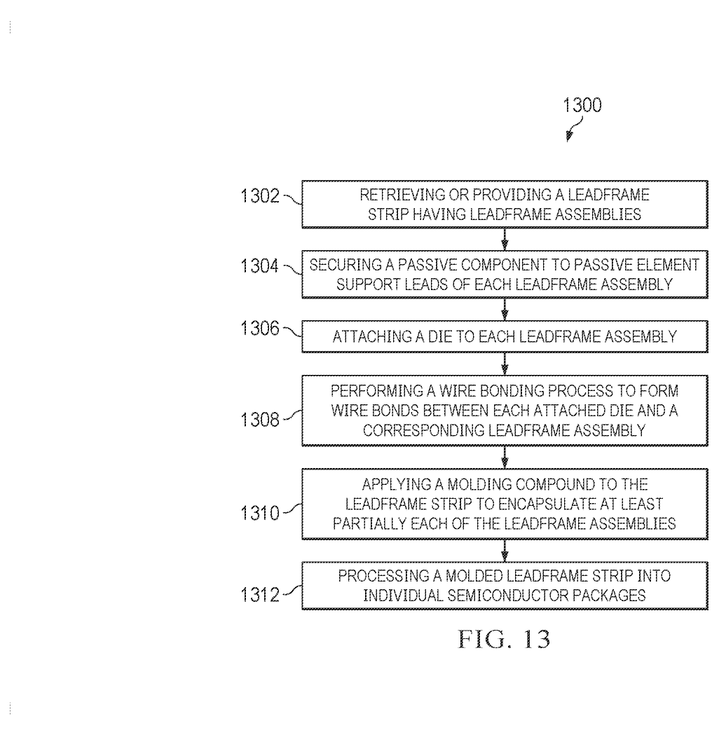

FIG. 12 is an example of another method 1200 for manufacturing a leadframe strip that includes the leadframe assembly 202, as illustrated in FIGS. 2A-2B, or the leadframe assembly 296, as illustrated in FIGS. 2C-2D. The leadframe strip can include multiple instances of the leadframe assembly 202 (or the leadframe assembly 296) and can be fabricated using a stamping technique. According to the examples herein, the leadframe strip can be manufactured such that each leadframe assembly includes the first and second passive element support leads 290-291, thereby providing bonding surfaces (e.g., the bottom surfaces 272) for attaching a passive element (e.g., the capacitor 270) during semiconductor package fabrication, as described herein.

At block 1202, the method 1200 can begin with retrieving or providing a metal sheet or metal strip composed of a conductive material, in some instances, as described herein. At block 1204, a die stamping (or punching) process can be used to form leadframe structures. The stamping system can include multiple stations that sequentially perform various operations on the metal sheet as the metal sheet advances through the stamping system. For example, each die station can perform a predefined cutting, forming, and/or punching operation to incrementally shape the metal sheet to provide the leadframe strip. The stamping process can define structural features of each leadframe assembly, such as the leadframe assembly 202, 296, including the passive element support leads 203, the connection leads 205, the die pad 226, the tie bars 208 (or the tie bars 298), the dam bars 204 and the carrier pads 210, as illustrated in FIGS. 2A-2D, respectively.

At block 1206, the metal sheet with formed leadframe assemblies can be output as a leadframe strip. In some examples, at block 1206, the leadframe strip can undergo a deburring and cleaning process to remove sharp edges and residual material from the stamping process. In some examples, a chemical or mechanical cleaning step can be performed to remove oxidation, particulate contaminants, or residual lubricants used during stamping. In some examples, at block 1206, a surface plating process can be applied to the leadframe strip to enhance solderability and oxidation resistance. The plating process can be performed using electroplating, immersion plating, or other metal deposition techniques.

FIG. 13 is an example of a method 1300 for fabricating a plurality of semiconductor packages similar to the semiconductor device 100, as illustrated in FIG. 1A, or the semiconductor device 1002, as illustrated in FIG. 10. The method 1300 can begin at block 1302 with retrieving or providing a leadframe strip that includes leadframe assemblies. The leadframe strip can be produced according to the example of method 1100 of FIG. 11 or the method 1200 of FIG. 12 in some instances. Each leadframe assembly of each leadframe strip can include passive element support leads (e.g., the first and second passive element support leads 290-291, as illustrated in FIGS. 2A-2D). At block 1304, a passive component can be secured (e.g., bonded, as described herein) to the passive element support leads of each leadframe assembly in a same or similar manner as described herein. Securing the passive component to the passive element support leads couples the passive element supports leads to each other, thereby forming an electrically conductive path across the passive component while maintaining electrical isolation between these respective leadframe sections.

At block 1306, a die (e.g., the die 702) can be attached to a die pad (e.g., the die pad 226) of each leadframe assembly in a same or similar manner as described herein. At block 1308, a wire bonding process can be performed to form wire bonds between each attached die and corresponding leadframe assembly of the leadframe strip, as described herein. In some examples, the wire bonding process can be used to electrically connect each die to the first and second passive element support leads in a same or similar manner as described herein. At block 1310, a mold compound can be applied to the leadframe strip to at least partially encapsulate the leadframe assemblies in a same or similar manner as described herein, resulting in a molded leadframe strip. For example, the molding compound encapsulates at least inner lead portions of the leadframe assemblies while leaving outer lead portions of the leadframe assemblies exposed. At block 1312, the molded leadframe strip is processed to produce individual semiconductor packages. For example, processing the molded leadframe strip can include isolating leads by trimming dam bars, shaping outer lead portions into a predetermined configuration and singulating the leadframe strip to provide the plurality of semiconductor packages.

In this description, unless otherwise stated, "about," "approximately" or "substantially" preceding a parameter means being within +/- 10 percent of that parameter. Modifications are possible in the described embodiments and other embodiments are possible within the scope of the claims.

What is claimed is:

1. A semiconductor package comprising:
a die;
a leadframe comprising:
a die pad to which the die is coupled; and
a set of leads comprising surfaces, wherein a passive component is coupled to the surfaces of the set of leads, which are at least in electrical connection with the die.

2. The semiconductor package of claim 1, wherein the passive component is coupled to a bottom side of the leadframe, the bottom side being opposite to a top side of the leadframe to which the die is coupled.

3. The semiconductor package of claim 1, wherein each lead of the set of leads comprises:
an outer lead portion that extends outward from the semiconductor package and establishes an electrical connection between the passive component and the external circuitry; and
an inner lead arm extending toward the die pad from a periphery portion of the semiconductor package, the inner lead arm having a surface of the surfaces to which the passive component is coupled.

4. The semiconductor package of claim 3, wherein the passive component includes first and second terminals, wherein:
the first terminal of the passive component is coupled to a first surface of the bonding surfaces of a first inner lead arm of a first lead of the set of leads; and
the second terminal of the passive component is coupled to a second surface of the surfaces of a second inner lead arm of a second lead of the set of leads.

5. The semiconductor package of claim 4, wherein the first and second terminals of the passive component are coupled to one of the first and second surfaces by a solder joint.

6. The semiconductor package of claim 1, wherein the set of leads comprises first and second leads and wherein:
the first lead comprises:
a first outer lead portion that extends outward from the semiconductor package;
a first inner lead arm extending from a periphery portion of the semiconductor package toward the die pad within the semiconductor package, the first inner lead arm having a first surface of the surfaces;
the second lead comprises:
a second outer lead portion that extends outward from the semiconductor package;
a second inner lead arm extending from the periphery portion of the semiconductor package toward the die pad within the semiconductor package, the second inner lead arm having a second surface of the surfaces; and
wherein a first terminal of the passive component is coupled to the first surface of the first inner lead arm and a second terminal of the passive component is coupled to the second surface of the second inner lead arm.

7. The semiconductor package of claim 6, wherein the first inner lead arm comprises:
a first transition region connecting the first outer lead portion to a first intermediate segment;
the first intermediate segment extending from the first transition region toward a second transition region;
the second transition region connecting the first intermediate segment to a first terminal segment; and
the first terminal segment comprising the first surface to which the first terminal of the passive component is coupled.

8. The semiconductor package of claim 7, wherein the second inner lead arm comprises:
a second intermediate segment connecting the second outer lead portion to a third transition region;
the third transition region connecting the second intermediate segment to a second terminal segment; and
the second terminal segment comprising the second surface to which the second terminal of the passive component is coupled.

9. The semiconductor package of claim 8, wherein the first and second terminal segments have a top surface and bottom surface, the first surface corresponding to the bottom surface of the first terminal segment and the second surface corresponding to the bottom surface of the second terminal segment.

10. The semiconductor package of claim 9, wherein:
a first wire is bonded to the top surface of the first terminal segment; and
wherein a second wire is bonded to the top surface of the second terminal segment.

11. The semiconductor package of claim 8, wherein:
the set of leads are passive element support leads; and
the first terminal segment and the second terminal segment are located within a die-to-lead separation region corresponding to a gap between at least some of inner lead segments of connections leads of the semiconductor package and an edge of the die pad.

12. The semiconductor package of claim 9, wherein:
the first terminal segment has a first end portion and the second terminal segment has a second end portion; and
a width of the first end portion and a width of the second end portion are about equal to or greater than a width of the first and second terminals of the passive component.

13. A method comprising
providing one or more leadframe assemblies, each leadframe assembly comprising a die pad and a set of leads, each lead of the set of leads comprising an inner lead arm extending toward the die pad from a periphery portion of a respective leadframe assembly;
attaching a passive component to the inner lead arms;
attaching a die to the die pad of each leadframe assembly;
forming electrical connections between the die and the respective leadframe assembly;
applying a molding material to encapsulate at least a portion of each leadframe assembly to provide one or more molded leadframe assemblies; and
processing the one or more molded leadframe assemblies to form one or more semiconductor packages.

14. The method of claim 13, wherein the attaching the passive component comprises attaching first and second terminals of the passive component to respective surfaces of corresponding first and second inner lead arms using solder.

15. The method of claim 13, wherein each lead of the set of leads comprises:
an outer lead portion positioned at the periphery portion of the leadframe and extending away from the die pad; and
the inner lead arm that extends toward the die pad from the periphery portion of the semiconductor package, each inner lead arm having a surface to which a respective terminal of the passive component is coupled.

16. The method of claim 13, wherein the attaching the passive component comprises:
flipping each leadframe assembly to orient a back side of each leadframe assembly opposite to a top side to which the die is attached to the die pad; and
attaching the passive component to the back side of the leadframe assembly, wherein the passive component is coupled to bottom surfaces of the inner lead arms, the bottom surfaces being opposite to top surfaces of the inner lead arms on the top side of the leadframe assembly.

17. The method of claim 14, wherein the one or more leadframe assemblies are part of a leadframe strip and the leadframe strip is produced by a stamping or etching process to define structural features of each leadframe assembly, including the die pad and the set of leads.

18. A method comprising:
providing a leadframe strip comprising multiple leadframe assemblies, each leadframe assembly including a die pad and a set of leads, each lead of the set of leads comprising an inner lead arm extending toward the die pad from a periphery portion of the leadframe assembly;
attaching a passive component to the inner lead arms of each leadframe assembly in the leadframe strip;
attaching a die to the die pad of each leadframe assembly;
forming electrical connections between each die and the corresponding leadframe assembly;
applying a molding material to encapsulate at least a portion of each leadframe assembly, thereby providing a molded leadframe strip; and
processing the molded leadframe strip to form a plurality of semiconductor packages by separating individual leadframe assemblies from the molded leadframe strip.

19. The method of claim 18, wherein the leadframe strip is produced by a stamping or etching process to define structural features of each leadframe assembly, including the die pad and the set of leads.

20. The method of claim 18, wherein attaching the passive component comprises:
flipping the leadframe strip from an initial orientation in which a top side of the leadframe strip faces upward to an inverted orientation in which a back side of the leadframe strip faces upward, the back side being opposite to the top side; and
securing the passive component to the back side of each leadframe assembly of the leadframe strip, wherein the passive component is coupled to bottom surfaces of the inner lead arms, the bottom surfaces being opposite to top surfaces of the inner lead arms on the top side of the leadframe strip.
